(19) United States
(12) Patent Application Publication
(10) Pub. No.: US 2022/0195205 A1
(43) Pub. Date: Jun. 23, 2022

(54) A Multi-Layered Coating

(71) Applicant: AGENCY FOR SCIENCE TECHNOLOGY AND RESEARCH, Singapore (SG)

(72) Inventor: Mark Allen Moxey, Singapore (SG)

(21) Appl. No.: 17/440,051

(22) PCT Filed: Mar. 18, 2020
(86) PCT No.: PCT/SG2020/050143

§ 371 Date: Sep. 16, 2021

(30) Foreign Application Priority Data
Mar. 18, 2019 (SG) 10201902396V

(51) Int. Cl. C09D 5/00; C09D 7/61; G02B 1/118; G03F 7/027; G03F 7/00; G03F 7/004; G03F 7/075; C09D 201/00

(52) U.S. Cl. CPC C09D 5/006; C09D 7/61; G02B 1/118; G03F 7/027; C09D 201/00; G03F 7/0005; G03F 7/0047; G03F 7/0755; G03F 7/0002

(57) ABSTRACT

There is provided a multi-layered coating having a plurality of cavities therein, the multi-layered coating comprises a first layer comprising an oxide-containing polymer; and a second layer disposed on said first layer, said second layer comprising an oxide. There is also provided a process for forming such multi-layered coating, an article comprising the multi-layered coating and uses thereof.

### CROSS REFERENCE TO RELATED APPLICATIONS

This application makes reference to and claims the benefit of priority of an application for “Durable Anti-Reflection Anti-Fog Single Layer Coating” filed on 18 Mar. 2019 with the Intellectual Property Office of Singapore, and duly assigned application number 10201902396V. The content of the above application filed on 18 Mar. 2019 is incorporated herein by reference for all purposes, including an incorporation of any element or part of the description, claims or drawings not contained herein.

### TECHNICAL FIELD

The present invention generally relates to a multi-layered coating. The multi-layered coating may have anti-reflection, anti-fog and abrasion resistance properties. The present invention also relates to a process for forming such multi-layered coatings, an article comprising the same and uses thereof.

### BACKGROUND ART

Optically clear substrate, such as glass or certain plastics, finds applications in eyewear (which can include spectacle lenses, visors or goggles), windows (which can include automotive windshields or architectural glass), optical instruments, and digital displays. For different applications, one or more surface properties, such as abrasion resistance, anti-fog, and anti-reflection are highly attractive and practical to have because they enhance the usability of the transparent material.

In cases where the substrate is used in a high humidity place or at a boundary of a large temperature/humidity difference, fogging or condensation of water vapor may occur on the surface of the substrate, which reduces its transparency. In cases where the substrate is exposed to elements, abrasion resistance is a critical property of the substrate to ensure that the durability and transparency of the substrate surface are maintained. In cases where the substrate is used in a medium where the reflective index is different from that of the substrate, reflection caused light loss may reduce the transmittance of a transparent substrate. Accordingly, there has been no lack of attempts in the past to provide coatings to protect and increase the surface properties of the optically clear substrate.

There is previously described a coating composition comprising a porous silica nanoparticles, one or more organic soluble polymer resins, one or more UV-cross linkable resins, one or more UV cross linkable reactive diluents, solvents, and a UV-initiator system. However, the coating here is not abrasion resistant.

While coatings having properties of superhydrophilicity, high transparency, and antireflection exist, such coatings appear not to be abrasion resistant.

Hitherto, it has not been possible to combine all three properties of anti-reflection, anti-fog, and abrasion resistance in the same coating and achieve a high level of performance in a satisfactory manner.

Thus, there is a need to provide a multi-layered coating that overcomes, or at least ameliorates, one or more of the disadvantages described above. The multi-layered coating is preferably one that has anti-reflection, anti-fog and abrasion resistance properties.

There is also a need to provide a process for forming such multi-layered coatings.

### SUMMARY

According to a first aspect, there is provided a multi-layered coating having a plurality of cavities therein, the multi-layered coating comprises a first layer comprising an oxide-containing polymer; and a second layer disposed on the first layer, the second layer comprising an oxide.

Advantageously, the multi-layered coating may have anti-reflection, anti-fog and abrasion resistance properties. The multi-layered coating may also be optically clear or transparent so as to allow light to substantially pass through the multi-layered coating from one side of the coating to another (usually opposite) side, so as to allow a user to look through the multi-layered coating with minimal optical interference or impediment.

Advantageously, by having more than one property in one coating, this negates the need for a number of individual coatings to be used. Therefore, this not only reduces the number of individual coatings required, but is also able to reduce the need of layering the coating to achieve different properties.

According to a second aspect, there is provided a process of forming a multi-layered coating having a plurality of cavities therein, the process comprising the steps of:

a. applying an oxide-containing polymer onto a substrate to form a first layer;

b. contacting the oxide-containing polymer with a mold to imprint a plurality of cavities therein the first layer;

c. polymerizing the oxide-containing polymer while in contact with the mold; and

d. oxidizing the first layer to form a second layer disposed on the first layer, the second layer comprising an oxide.

Advantageously, the process may be a simple process in order to form a multi-layered coating having at least the above properties of anti-reflection, anti-fog and abrasion resistance. The process may be scalable depending on the size of the mold.

Advantageously, the second layer may be formed in situ and does not require a separate layer to be applied into the first layer. The second layer is formed as a result of a chemical reaction and does not require adhesion or physical means to adhere to the first layer. Therefore, the process optionally does not require an adhering step or a physical placement of the second layer onto the first layer.

According to a third aspect, there is provided an article comprising a multi-layered coating thereon, the multi-layered coating having a plurality of cavities therein and comprises a first layer comprising an oxide-containing polymer; and a second layer disposed on the first layer, the second layer comprising an oxide.

### Definitions

The following words and terms used herein shall have the meaning indicated:

The term ‘cavity’ is to be interpreted broadly to include a recess or a hole that extends from the surface of the coating into the body or bulk material of the coating. This is opposed to a projection or a protrusion that extends outward from the surface of the coating.

The term ‘curable’ is to be interpreted broadly to refer to the ability of a resin/monomer to be hardened or toughened by covalent cross-linking to each other, brought about by chemical additives, ultraviolet radiation, electron beam or heat.

The term ‘UV-curable’ is to be interpreted broadly to refer to the ability of a resin/monomer to be hardened or toughened by covalent cross-linking to each other, brought about by ultraviolet radiation.

The term ‘cross-linking’ is to be interpreted broadly to refer to forming covalent bonds or crosslinks between monomers to form polymers, or between polymers, for example, linear polymers, branched polymers, dendrimers, or macromolecular molecules. Here, the cross-linking may also refer to covalent bonds or crosslinks between a molecule and a polymer. The term ‘cross-linker’ or ‘cross-linking agent’ refers to a compound or a mixture of compounds capable of forming crosslinks in such a context.

The term ‘nanoimprint process’ is to be interpreted broadly to refer to a process to make coatings comprising imprinted surface structures in the nano-sized range.

The term “optically clear” is to be interpreted broadly to refer to a property of the coating whereby the coating is substantially transparent and allows light to pass through the coating from one side to another (usually opposite) side of the coating. This is opposed to translucent or opaque. Optically clear coatings are usually colorless and remain that way.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### Detailed Disclosure of Embodiments

Exemplary, non-limiting embodiments of a multi-layered coating will now be disclosed.

The multi-layered coating has a plurality of cavities therein, the multi-layered coating comprises a first layer comprising an oxide-containing polymer; and a second layer disposed on the first layer, the second layer comprising an oxide.

The size of the cavities may be in the nanometer scale. The size of the cavities may be regarded as being smaller than the wavelength of visible light. The size of the cavities may be in the range of about 100 nm to about 380 nm, about 150 nm to about 380 nm, about 200 nm to about 380 nm, about 250 nm to about 380 nm, about 300 nm to about 380, about 350 nm to about 380 nm, about 100 nm to about 350 nm, about 100 nm to about 300 nm, about 100 nm to about 250 nm, about 100 nm to about 200 nm, or about 100 nm to about 150 nm.

The size of the cavity may be regarded as a dimension of the cavity when measured at the surface of the coating. The dimension may depend on the shape of the cavity when viewed from the top of the coating. Where the cavity is viewed as one having a circular shape, the dimension may be regarded as the diameter and depth of the circular shape. Where the plurality of cavities is viewed as an array, the dimension may be regarded as the period of the array, which is the distance from one point of a cavity to the same point but of a neighbouring cavity.

The cavity may have a shape selected from a dimple shape, a cylindrical shape, a conical shape, or a conical frustum shape. Therefore, the sides of the cavity may form a perpendicular angle with the surface of the coating or may be angled relative to the surface of the coating. The base of the cavity (that is present within the coating) may be substantially straight or curved.

The plurality of cavities may form a honeycomb-like structure where the cavities are circular-shaped when viewed from the top of the coating.

Due to the presence of cavities that are dimensioned smaller than the wavelength of visible light, this may lead to the anti-reflection property of the multi-layered coating. While projections that extend from the surface of a coating can also confer an anti-reflection property, this is not desirable in the present application as such projections can be brittle and can be damaged easily when a shear force is applied onto the coating, leading to the removal of the projections when a shear force is applied. Having cavities in the coating ensure that the cavities are undamaged and intact in the presence of a shear force, thereby maintaining the anti-reflection property of the coating.

The size of the cavities being in a range smaller than the wavelength of visible light may form a gradient of refractive index (GRIN) which is required for the anti-reflective effect. This gradient of refractive buffers the transition of light as it passes from air to solid medium, resulting in less reflection and thus higher transmission.

In the multi-layered coating, the oxide of the oxide-containing polymer and the oxide in the second layer is the same. The oxide of the second layer may be formed when oxidizing the first layer in order to retain the oxide and remove the organic components. Therefore, the oxide has to be part of the material used to form the first layer. The oxide of the second layer may confer the anti-fogging property to the multi-layered coating due to the ability of the oxide to create a superhydrophilic surface. Therefore, any exposure of the multi-layered coating to water vapour results in the formation of a water film on the surface which helps to avoid the negative appearance of fog. Any oxide that is able to form a superhydrophilic surface may be used. Exemplary types of oxides include silica (SiO₂), titanium oxide (TiO₂) and zinc oxide (ZnO).

In the multi-layered coating, the polymer is formed by UV-curable resins. The UV-curable resin may contain monomers with multiple reactive groups to facilitate cross-linking of the cured polymer chains, which is the process to harden the cured polymer and therefore to confer the abrasion resistance property of the multi-layered coating.

The UV-curable resin may be polymerized by monomers selected from the group consisting of (meth)acrylates, esters, epoxy resins, urethanes, silicones, ethers and vinyl ethers. The UV-cured resin may be epoxy (meth)acrylates, acrylated polyesters, acrylate modified urethanes or acrylated silicones. Some examples of UV-cured resins are, but not limited to, diglycidyl ether of bisphenol A (DGEBA), hexanediol diacrylate (HDDA), dipentaeryth ritol hexaacrylate (DPHA), tripropylene glycol diacrylate (TPGDA), pentaerythritol triacrylate (PETA), or derivatives thereof. The photo-initiator used in the polymerization process is 2-Hydroxy-2-methylpropiophenone.

The first layer may have a thickness in the range of about 1 μm to about 100 μm, about to about 90 μm, about 1 μm to about 80 μm, about 1 μm to about 70 μm, about 1 μm to about 60 μm, about 1 μm to about 50 μm, about 1 μm to about 40 μm, about 1 μm to about 30 μm, about 1 μm to about 20 μm, about 1 μm to about 10 μm, about 10 μm to about 100 μm, about 20 μm to about 100 μm, about 30 μm to about 100 μm, about 40 μm to about 100 μm, about 50 μm to 100 μm, about 60 μm to about 100 μm, about 70 μm to about 100 μm, about 80 μm to about 100 μm, or about 90 μm to about 100 μm. The second layer may have a thickness in the range of about 1 nm to about 50 nm, about 1 nm to about 40 nm, about 1 nm to about 30 nm, about 1 nm to about 20 nm, about 1 nm to about 10 nm, about 10 nm to about 50 nm, about 10 nm to about 50 nm, about 20 nm to about 50 nm, about 30 nm to about 50 nm, or about 40 nm to 50 nm.

The multi-layered coating may be substantially optically clear.

Exemplary, non-limiting embodiments of a process of forming a multi-layered coating having a plurality of cavities therein will now be disclosed.

The process comprises the steps of:

a. applying an oxide-containing UV-curable resin onto a substrate to form a first layer;

b. contacting the oxide-containing UV-curable resin with a mold to imprint a plurality of cavities therein the first layer;

c. polymerizing the oxide-containing UV-curable resin while in contact with the mold; and

d. oxidizing the first layer to form a second layer disposed on the first layer, the second layer comprising an oxide.

The second layer may be formed in situ on the first layer and therefore, an additional layering step is not required. The second layer adopts the shape and conformation of the first layer easily (including those of the cavities) due to the in situ formation of the second layer on the first layer. Since additional layering steps are not used (which can be difficult to ensure that the added layer conforms exactly to the shape and conformation of the first layer), this process avoids the need for such conformity and ensures that the integrity of the cavities is maintained.

The oxide-containing polymer may be an oxide-containing UV-cured resin. The UV-cured resin may be polymerized by UV-curable resins which comprise monomers selected from the group consisting of (meth)acrylates, esters, epoxy resins, urethanes, silicones, ethers and vinyl ethers. The UV-curable resin may be epoxy (meth)acrylates, acrylated polyesters, acrylate modified urethanes or acrylated silicones. Some examples of UV-curable resins are, but not limited to, diglycidyl ether of bisphenol A (DGEBA), hexanediol diacrylate (HDDA), dipentaeryth ritol hexaacrylate (DPHA), tripropylene glycol diacrylate (TPGDA), pentaerythritol triacrylate (PETA), or derivatives thereof. The UV-cured resin may be polymerized in the presence of a photo-initiator that is activated by UV-light may cause the UV-curable resin to polymerise and thereby cure, forming a UV-cured resin. The UV-curable resin may contain additives as required.

The oxide-containing polymer may be polymerized when in contact with the mold. The mold may have a plurality of projections that form corresponding cavities when applied onto the first layer such that upon polymerizing, the plurality of cavities is imprinted into the first layer. The plurality of cavities may be imprinted via nanoimprinting lithography.

The contacting step may be undertaken at a room temperature and pressure in the range of about 5 bars to about 20 bars, about 5 bars to about 15 bars, about 5 bars to about 10 bars, about 10 bars to about 20 bars, or about 15 bars to about 20 bars.

The polymerizing step may be undertaken at a room temperature and pressure in the range of about 5 bars to about 20 bars, about 5 bars to about 15 bars, about 5 bars to about 10 bars, about 10 bars to about 20 bars, or about 15 bars to about 20 bars.

The oxidizing step may be undertaken by a manner of deep reactive-ion etching (DRIE), using oxygen gas under high oxygen pressure with low power at a room temperature. The oxygen pressure is about less than 1 mbar, such as in the range of about 0.1 mbar to about 0.9 mbr, about 0.1 to about 0.8 mbar, about 0.1 mbar to about 0.7 mbar, about 0.1 mbar to about 0.6 mbr, about 0.1 mbar to about 0.5 mbar, about 0.2 mbar to about 0.9 mbar, about 0.3 mbr to about 0.9 mbr, about 0.4 mbr to about 0.9 mbr, or about 0.5 mbr to about 0.9 mbr.

The multi-layered coating may be applied onto an article in order to confer desirable properties to the article. Therefore, there is also provided an article comprising a multi-layered coating thereon, the multi-layered coating having a plurality of cavities therein and comprises a first layer comprising an oxide-containing polymer; and a second layer disposed on the first layer, the second layer comprising an oxide.

The multi-layered coatings can be used in a number of applications such as those mentioned below.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 is a schematic diagram illustrating (A) the cross-section and (B) the top view of the nanostructured coating.

FIG. 2 is a schematic diagram indicating the effects of shear force applied to (A) a hole or (B) pillar type structure.

FIG. 3 is a number of scanning electron microscope (SEM) images of nanostructured coating, comparing (A) hole type and (B) pillar type structures (i) and (iii) before and (ii) and (iv) after rubbing with a spectacle cloth, 320 revolutions with approximate 200 g to 300 g pressure.

FIG. 4 is a schematic diagram showing the gradient refractive index (GRIN) created by an array of nano-scale dimple structures.

FIG. 5 is a graph showing the percentage of reflected light measured across the visible light spectrum, comparing a coating with pillar type and hole type structures coated on acrylic as substrate.

FIG. 6 is a graph showing the percentage of reflected light measured across the visible light spectrum, comparing the present invention coating with a commercially available anti-reflective coating (Shamir) and a control substrate with no anti-reflective coating. The control substrate is made of material CR-39, which is a type of polycarbonate used for making spectacle lenses.

FIG. 7 is a schematic diagram showing how the (A) silicon content of the polymer coating can be concentrated at the coating surface to form (B) an oxide surface, by a process of strong oxidation, increasing the hydrophilicity of the coating.

FIG. 8 is a number of X-ray photoelectron spectroscopy (XPS) spectra of (a) silicon coating, (b) silicon containing coating after surface oxidation, (c) non-silicon containing coating, and (d) non-silicon containing coating after surface oxidation.

FIG. 9 is an overlay image of the XPS silicon 2p narrow scans over a range of oxidation exposure times for the current invention coating (silicon containing) and control coating (non-silicon containing).

FIG. 10 is a number of images taken of the anti-fogging test showing steps (i) a sample before steam exposure, (ii) sample initiating steam exposure, (iii) sample being exposed to steam, and (iv) sample immediately after steam exposure; and showing (a) the apparatus used to produce a steady supply of steam, (b) (i-iv) a sample with current invention coating having undergone surface oxidation, (c) (i-iv) a sample with identical coating as in (B) (i-iv) which has not undergone surface oxidation and (D) (i-iv) same sample as in (B) (i-iv), 14 days after undergoing surface oxidation.

### DETAILED DESCRIPTION OF FIGURES

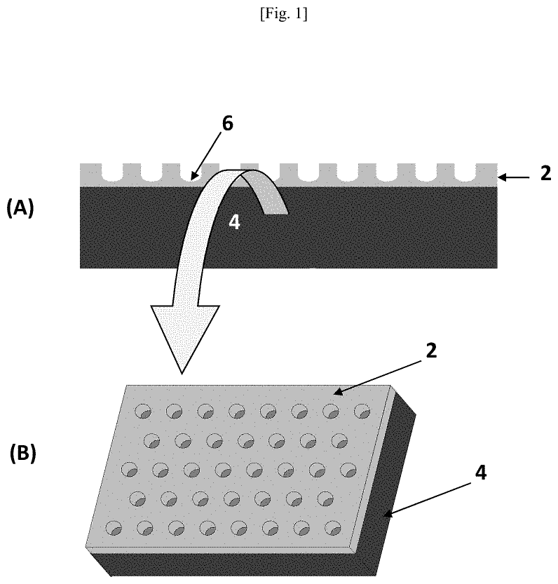

Referring to FIG. 1, there is provided a schematic diagram illustrating (A) the cross-section and (B) the top view of a multi-layered coating in the form of a nanostructured coating 2 provided on a substrate 4. The nanostructured coating 2 is shown as having a plurality of cavities in the form of dimples 6. The nanostructured coating 2 is one that is made up of a first layer comprising an oxide-containing polymer and a second layer disposed on the first layer, where the second layer comprises an oxide.

### EXAMPLES

Non-limiting examples of the invention will be further described in greater detail by reference to specific Examples, which should not be construed as in any way limiting the scope of the invention.

### Example 1

### A Multi-layered Coating

A multi-layered coating with an array of dimples was formed by the method of nanoimprint lithography. Here, a UV-curable resin was made from a mixture of the following chemicals: MA0736—Acrylo POSS Cage Mixture (Hybrid Plastics, Mississippi, USA), 1,6-hexanediol diacrylate (Sigma-Aldrich, Missouri, USA), Pentaerythritol tetrakis(3-mercaptopropionate) (Sigma-Aldrich, Missouri, USA), isobornyl acrylate (Sigma-Aldrich, Missouri, USA), 3-(Trimethoxysilyl)propyl methacrylate (Sigma-Aldrich, Missouri, USA) and 2-Hydroxy-2-methylpropiophenone (Sigma-Aldrich, Missouri, USA). Among the above, MA0736—Acrylo POSS Cage Mixture (Hybrid Plastics, Mississippi, USA) and 1,6-hexanediol diacrylate (Sigma-Aldrich, Missouri, USA) were used for providing the coating. Pentaerythritol tetrakis(3-mercaptopropionate) (Sigma-Aldrich, Missouri, USA) is a monomer used to increase cross-linking and to reduce oxygen inhibition of the polymerization. Isobornyl acrylate (Sigma-Aldrich, Missouri, USA) is a monomer which increases adhesion of the cured polymer to the substrate. 3-(Trimethoxysilyl)propyl methacrylate (Sigma-Aldrich, Missouri, USA) is a silicon containing chemical, which increases the concentration of silicon at the surface of the polymer and it can increase adhesion to oxide substrates. 2-Hydroxy-2-methylpropiophenone is the photo-initiator. The as-prepared UV curable resin was applied onto a substrate 4, as shown in FIG. 1. A stamp with a topographical pattern was used to imprint the resin to form the negative of the stamp's topography 6, where the array of dimples 6 was formed. Whilst the stamp was in contact with the resin, UV radiation was used to cure the resin in order to create the array of dimples 6. When the array of dimples 6 was consolidated, the stamp was removed.

The formed multi-layered coating is then subjected to a number of characterization processes.

### Shear Force

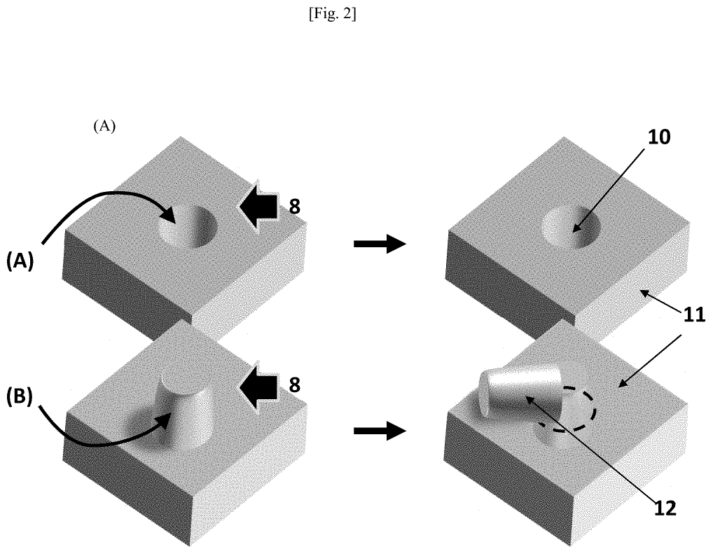

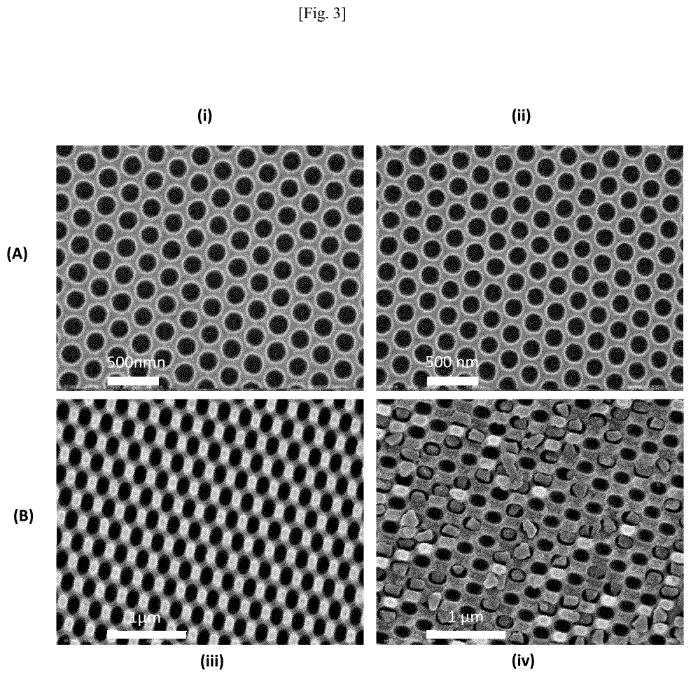

In order to show that cavities were more resistant to shearing as compared to projections, the multi-layered coating with the plurality of cavities was subjected to a shear force test. Conventionally, arrays of pillar type projections were used to confer the anti-reflection properties to the coating. However, such pillar type structures cannot cope with abrasive forces because the pillars were brittle and fragile to shear forces. Here, it can be seen that cavity structures 10 on nanostructured coating 11 were much less susceptible to damage by shear force 8 as compared to pillar type structures 12 as illustrated in FIG. 2. FIG. 2 provides a schematic diagram indicating the effects of shear force 8 applied to (A) a cavity structure 10 and (B) pillar type structure 12 on a nanostructured coating 11. The cavity structure 10 was relatively unaffected by the shear force 8, whereas the pillar structure 12 was easily broken and removed by the shear force 8. FIG. 3 shows experimental data, which compares SEM images of cavity-type and pillar-type nanostructured coatings before and after 320 cycles of abrasive rubbing. The images of the surfaces after rubbing clearly show that the cavity type structures remained undamaged and intact, whereas the pillar type structures were almost totally destroyed. The anti-abrasion property was tested by using a spectacle cloth to rub the surface in a circular motion with the thumb at an applied load of between 200-300 g. The sample was placed on a scale whilst being rubbed to ensure the pressure remained between 200-300 g. The pillar coating was made from the same material as the hole structure. Comparing (A) hole type and (B) pillar type structures (i) and (iii) before and (ii) and (iv) after, a result shown the coating with of hole structures are well maintained in FIG. 3.

### Anti-Reflection

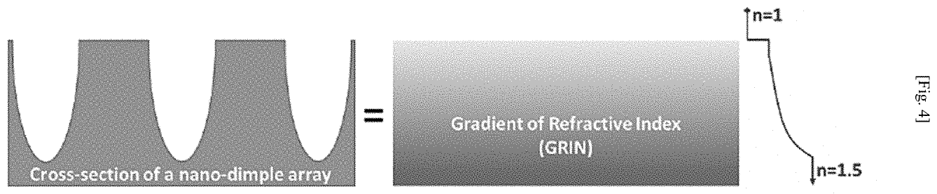

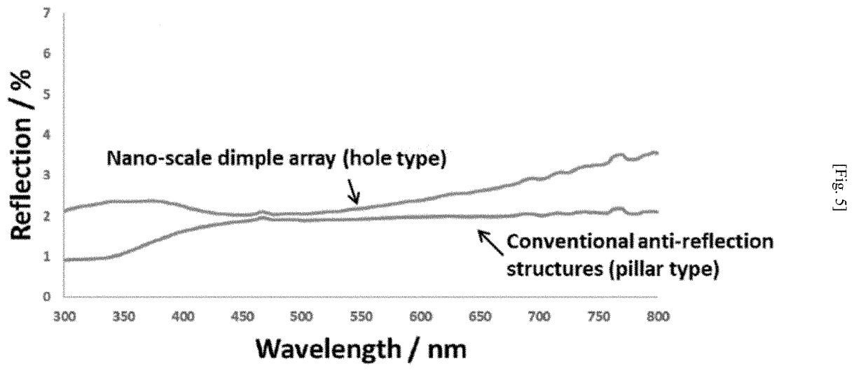

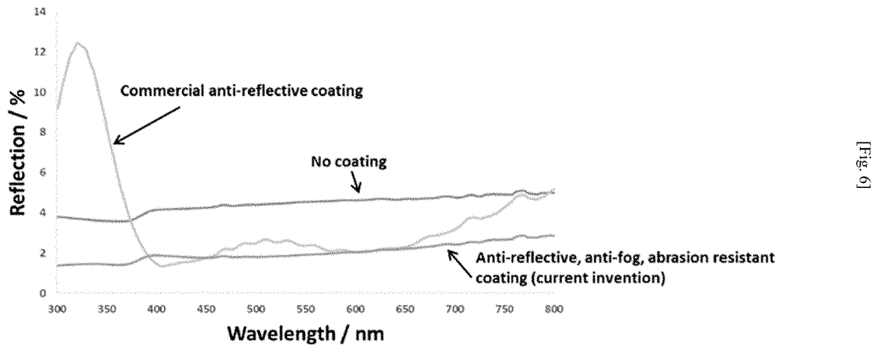

The anti-reflection properties were acquired using an array of structures with dimensions smaller than the wavelength of visible light. As show in FIG. 4, the cavity type structures can create the gradient of refractive index (GRIN) that is required for the anti-reflective effect. Although there was a loss of anti-reflection performance as compared to that of pillar type projections, as shown in the refection spectrum (see FIG. 5), the level of anti-reflection produced by the cavity structures was still significant and highly competitive with anti-reflective coatings commercially available as shown in FIG. 6.

### Anti-Fogging

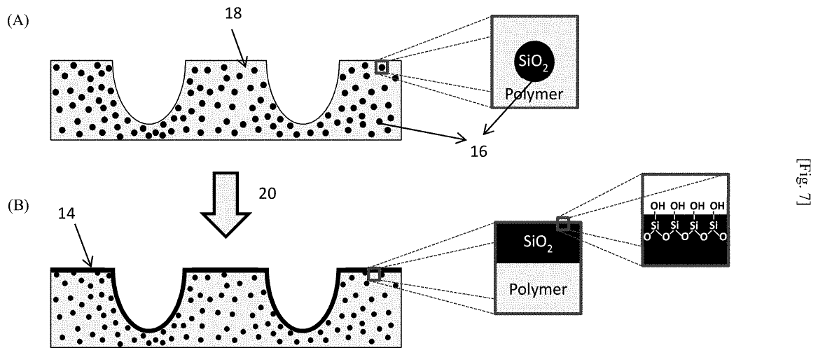

Anti-fogging properties can be obtained by creating a superhydrophilic surface that will facilitate the immediate formation of a water film of the surface, avoiding the negative appearance of fog. As seen in FIG. 7, a superhydrophilic surface 14 was created by oxidizing 20 a silicon contained polymer polyoctahedral silsesquioxanes (POSS) 18 with O₂ plasma to concentrate the silica 16 at the surface through removing the organic components, as illustrated in FIG. 7. The SiO2 formed at the surface produced a superhydrophilic surface with a water contact angle of less than 10°.

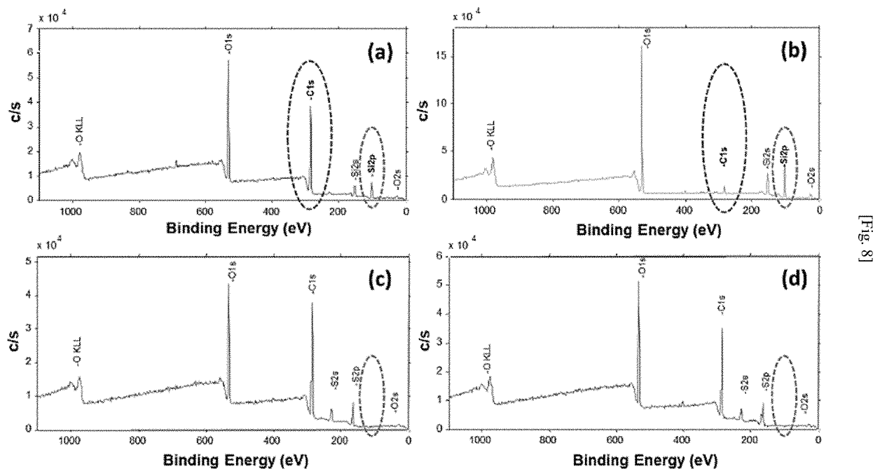

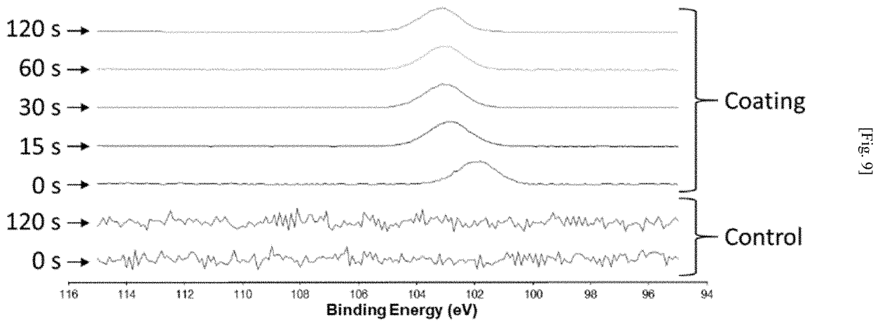

XPS characterization of the coating surface taking (a) before and (b) after oxidation treatment, and a control surface (non-silicon containing coating) taken (c) before and (d) after oxidation treatment is shown in FIG. 8. The control surface was made by the same resist formulation as used in the invention coating, except for the Si containing monomers. The resist only contained the following chemicals: 1,6-hexanediol diacrylate, Pentaerythritol tetrakis(3-mercaptopropionate), isobornyl acrylate and 2-Hydroxy-2-methylpropiophenone. Comparison of the spectra before and after oxidation of the coating (FIG. 8 (a) and Fig. (b)) showed a dramatic reduction in carbon peak intensity and a significant increase in silicon peak intensity, which was consistent with the removal of organic material and subsequent increase in the concentration of silicon material at the surface of the coating. The change in elemental composition of the surface is further clarified in Table 1, which shows that when the oxidation times was increased from 0 seconds to 120 seconds, the carbon % decreased from 65.9% to 10.8% while the oxygen and silicon % increased from 29.0% and 5.1% to 64.7% and 24.0%, respectively. Conversely, the % composition for carbon and oxygen in the control samples showed very little change. FIG. 9 shows the overlay of the Si 2p peaks, with their binding energies tabulated in Table 2. The peaks shift from 101.9 eV to 103.2 eV with increased oxidation, which was consistent with the transformation of organo-silicon to SiO₂.

TABLE 1
Element composition % at increasing oxidation times

| Sample | O₂ Exposure/s | C1s (%) | O1s (%) | Si2p (%) |
|---|---|---|---|---|
| 1 | 0 | 65.9 | 29.0 | 5.1 |
| 2 | 15 | 30.0 | 52.5 | 17.0 |
| 3 | 30 | 20.1 | 59.6 | 20.0 |
| 4 | 60 | 13.7 | 63.0 | 22.1 |
| 5 | 120 | 10.8 | 64.7 | 24.0 |
| Control 1 | 0 | 74.6 | 25.4 | 0.0 |
| Control 2 | 120 | 79.4 | 20.6 | 0.0 |

TABLE 2
Si 2p peak position at different oxidation times

| O₂ Exposure/s | Si 2p/eV |
|---|---|
| 0 | 101.9 |
| 15 | 102.8 |
| 30 | 103.0 |
| 60 | 103.0 |
| 120 | 103.2 |

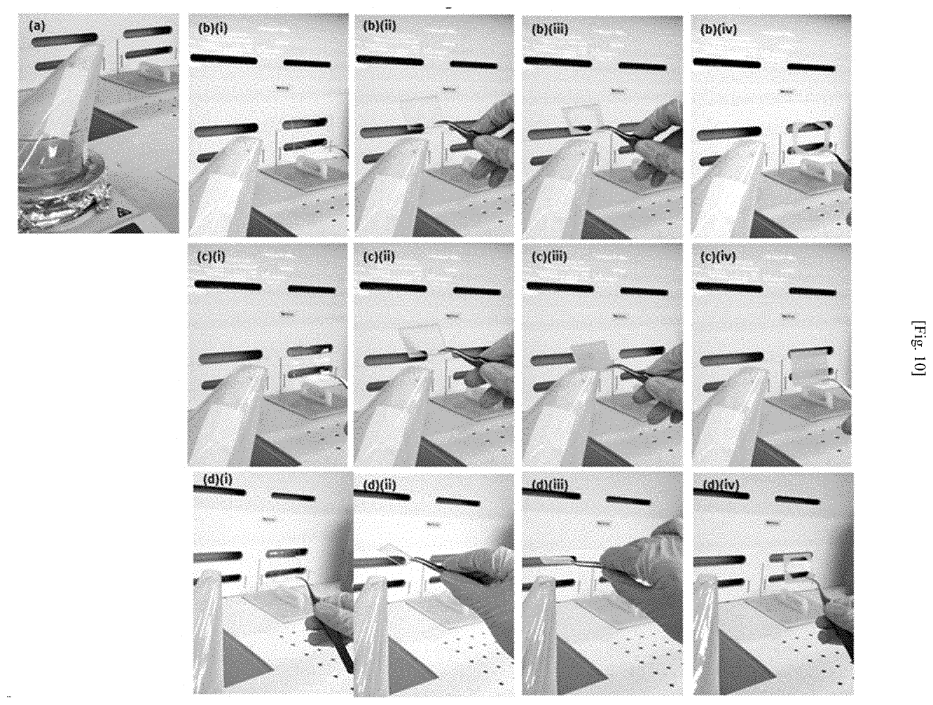

To demonstrate the anti-fogging properties, samples were exposed to a flow of steam to simulate a fogging environment. FIG. 10 shows a series of images taken of the fogging test. The tests were carried out using a home-made setup to produce a concentrated supply of steam as shown in FIG. 10 (a). The tested samples consisted of square pieces of acrylic with an area of imprinted coating in the centers. The sample shown in FIG. 10(b)(i-iv) had undergone surface oxidation and displayed no detectable fogging or any other visual impairment to the coated area of the sample when exposed to the steam. Conversely, the sample shown in FIG. 10(c)(i-iv) had not undergone any surface oxidation treatment, and the sample experienced extensive fogging when exposed to the steam. The same sample shown in FIG. 10(b)(i-iv) was tested again 14 days later to determine any loss in the anti-fogging effect as shown in FIG. 10(d)(i-iv), in which no measurable loss was detected.

Therefore, this shows that the coating of the present application is able to have anti-fogging properties that remain even after a period of time.

### INDUSTRIAL APPLICABILITY

The multi-layered coating may be used in optical applications such as eyewear (which can include spectacle lenses, visors or goggles) as well as in digital displays, camera lenses or photovoltaics. This may be due to the advantageous properties of the multi-layered coating such as anti-reflective, anti-fogging and abrasion resistant. Depending on the application required, the multi-layered coating may be optically clear or transparent so that where the multi-layered coating is used on devices, this does not impede the eyesight or vision of a user using such devices.

The multi-layered coating may find application in various optoelectronic equipment, aeronotical displays and sensors, automotive displays and sensors, space technologies and head-up display (HUD) devices as emitters and in displays.

The multi-layered coating may also be applied to soft substrates, creating a hard, non-scratch surface on softer polymer substrates.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A multi-layered coating having a plurality of cavities therein, said multi-layered coating comprising:
a. a first layer comprising an oxide-containing polymer; and
b. a second layer disposed on said first layer, said second layer comprising an oxide.

2. The multi-layered coating according to claim 1, wherein a size of said cavities is in a nanometer scale.

3. The multi-layered coating according to claim 2, wherein said size of said cavities is in a range of 380 nm to 740 nm.

4. The multi-layered coating according to claim 1, wherein said cavities have a shape selected from a dimple shape, a cylindrical shape, a conical shape, and a conical frustum shape.

5. The multi-layered coating according to claim 1, wherein the oxide of said oxide-containing polymer and the oxide in said second layer are the same.

6. The multi-layered coating according to claim 5, wherein said oxide is selected from the group consisting of silica (SiO₂), titanium oxide (TiO₂), and zinc oxide (ZnO).

7. The multi-layered coating according to claim 1, wherein said polymer is a UV-cured resin.

8. The multi-layered coating according to claim 7, wherein said UV-cured resin comprises a monomer selected from the group consisting of (meth)acrylates, esters, epoxy resins, urethanes, silicones, ethers, and vinyl ethers.

9. The multi-layered coating according to claim 1, wherein said first layer has a thickness in a range of 1 μm to 100 μm and said second layer has a thickness in a range of 1 nm to 50 nm.

10. The multi-layered coating according to claim 1, wherein said multi-layered coating is substantially optically clear.

11. A process of forming a multi-layered coating having a plurality of cavities therein, the process comprising the steps of:
a. applying an oxide-containing UV-curable resin onto a substrate to form a first layer;
b. contacting said oxide-containing UV-curable resin with a mold to imprint a plurality of cavities in said first layer;
c. polymerizing said oxide-containing UV-curable resin while in contact with said mold; and
d. oxidizing said first layer to form a second layer disposed on said first layer, said second layer comprising an oxide.

12. The process according to claim 11, wherein said contacting step is undertaken at a room temperature under pressure of 5 bars to 20 bars.

13. The process according to claim 11, wherein said polymerizing step is undertaken at a room temperature under pressure of 5 bars to 20 bars.

14. The process according to claim 11, wherein said oxidizing step is undertaken at a room temperature of under pressure of less than 1 mbar.

15. An article comprising a multi-layered coating thereon, said multi-layered coating having a plurality of cavities therein and comprises:
a. a first layer comprising an oxide-containing polymer; and
b. a second layer disposed on said first layer, said second layer comprising an oxide.
